(19) United States
(12) Patent Application Publication
(10) Pub. No.: US 2006/0163728 A1
(43) Pub. Date: Jul. 27, 2006

(54) Semiconductor device and method for manufacturing semiconductor device

(75) Inventors: Hiroyuki Nakanishi, Soraku-gun (JP); Katsunobu Mori, Nara-shi (JP)

Correspondence Address: NIXON & VANDERHYE, PC, 901 NORTH GLEBE ROAD, 11TH FLOOR, ARLINGTON, VA, 22203, US

(73) Assignee: SHARP KABUSHIKI KAISHA, Osaka-shi (JP)

(21) Appl. No.: 11/334,485

(22) Filed: Jan. 19, 2006

(30) Foreign Application Priority Data
Jan. 21, 2005 (JP) 2005-014810

(51) Int. Cl. H01L 23/48

(52) U.S. Cl. 257/738

(57) ABSTRACT

A semiconductor device includes: a semiconductor chip having a plurality of electrode pads formed on a principal surface thereof; a sealing resin, which covers both (i) side surfaces of the semiconductor chip and (ii) a surface of the semiconductor chip opposite to the principal surface; and external connection pads, which are provided on both (I) the principal surface and (II) a surface of the sealing resin flush with the principal surface, and which are electrically connected to the electrode pads. Thus, a semiconductor device is provided which makes it possible to place external connection pads at wider intervals, and which makes it possible to widen wires and to place the wires at wider intervals.

This Nonprovisional application claims priority under 35 U.S.C. § 119(a) on Patent Application No. 014810/2005 filed in Japan on Jan. 21, 2005, the entire contents of which are hereby incorporated by reference.

### FIELD OF THE INVENTION

The present invention relates to (i) a semiconductor device to be installed or incorporated in an electronic device and (ii) a method for manufacturing the semiconductor device.

### BACKGROUND OF THE INVENTION

Portable devices have been miniaturized, upgraded, and thinned. Accordingly, there has been such a tendency that electronic parts to be installed in the devices are packaged at high density. Similarly, semiconductor IC packages have been required to be miniaturized and thinned. In order to keep pace with the miniaturization of the devices, a small package called CSP (chip size package) has been proposed. The CSP has a size equal or substantially equal to the size of a chip.

Many types of CSP are formed in substantially the same manner as is a QFP (quad flat package) or an SOP (small outline package), which is a conventional surface-mounted package. That is, instead of a metal frame which is used for the QFP or the SOP and which is made of Cu or a Fe—Ni alloy, a printed circuit board made mainly of a hard material (e.g., epoxy) or a flexible tape material is used. Then, semiconductor chips are die bonded onto die pads formed on the printed circuit board. The die bonding is carried out with the use of a die bonding paste or a die bonding film. Then, an electrode pad of each semiconductor chip is connected to a bonding pad provided at one end of a metal wire, such as a gold wire, formed on the printed circuit board. With this, the electrode pad is electrically connected to an external connection terminal of the printed circuit board through the bonding pad. Furthermore, the semiconductor chip and an area surrounding the semiconductor chip are sealed with an insulating resin. The sealing is carried out by way of transfer molding, potting, or printing. Finally, the semiconductor chips are divided into individual packages with the use of a grinding machine or a laser. In this manner, the CSP is manufactured. The CSP manufactured with the use of this technique is disclosed, for example, in Japanese Patent No. 3176542 (Tokkyo 3176542; registered on Apr. 6, 2001) (Patent Document 1).

Recently, packages called wafer level CSP have been in practical use. The wafer level CSP is formed by directly packaging a wafer having elements formed thereon. The wafer level CSP is also used as one type of the chip size packages. Many types of wafer level CSP are formed in the following manner. First, on the wafer having the elements formed thereon, rewired portions and an insulator are formed by a technique used in a wafer process, the rewired portions extending from an electrode pad of each semiconductor chip formed on the wafer to an external connection terminal, and the insulator serving to protect the rewired portions. Examples of the technique used in the wafer process include sputtering, photolithography, plating, and etching. Thereafter, the wafer is divided into individual CSPs.

The wafer level CSP is formed by packaging the wafer having the elements formed thereon. The wafer level CSP have an advantage over the aforementioned CSP in that: because a wafer on which a large number of semiconductor chips are mounted is processed into packages called CSPs, the cost of manufacturing can be reduced. Further, since the wafer level CSPs are divided into individual packages of a size equal to the size of the chips, the wafer level CSPs are ultimate small-sized packages of a size equal to the size of the chips. Such a wafer level CSP is introduced on pages 42 to 59 of the August 1998 issue of Nikkei Microdevices (published by Nikkei Business Publications, Inc.; issued on Aug. 1, 1998).

FIGS. 10(a) and 10(b) illustrate a basic structure of a conventional example of the wafer level CSPs. FIG. 10(b) is a cross-sectional view taken along surface S3 of FIG. 10(a). As illustrated in FIG. 10(b), a wiring portion corresponding to wires 24 is formed. First, a polymer passivation layer 22 is formed on semiconductor chips 20 (which are in the form of a wafer at this stage of the manufacturing process) by way of photolithography so that electrode pads 21 formed on each of the semiconductor chips 20 are exposed. On the polymer passivation layer 22, the wires 24 are formed by electrolytic plating. Generally, a metal thin film serving as the base for the wires is formed on the entire surface of the wafer with the use of a sputtering device. The metal is covered with a photoresist. Exposure is carried out with the use of an aligner, and a predetermined photoresist removing step is carried out with the use of a developing machine. In this way, a predetermined portion of the photoresist on which the wires need to be formed is removed. Furthermore, on the portion from which the photoresist has been removed, a material to be the wires 24 is formed by electrolytic plating or the like. After the wires 24 have been formed, the photoresist is entirely removed. Then, the metal film remaining between the wires 24 is etched with the use of a chemical or the like. Through these steps, the wires 24 become electrically independent patterns. Furthermore, a photosensitive polymer material 25 is applied over the entire surface of the wafer. The polymer material 25 is formed by photolithography such that a dicing portion (i.e., a portion along which the wafer are cut later) and portions on which external connection pads 26 are formed are exposed. Furthermore, solder balls are mounted or a soldering paste is printed on the exposed portions on which the external connection pads 26 are formed. The mounted solder balls or the printed soldering paste is subjected to reflowing such that the external connection terminals 26 are formed.

Further, there is such a structure that a substrate on which wires are have been formed in advance is laminated on a wafer. The substrate on which the wires are formed is obtained, for example, in the following manner. First, a layer made up of an insulator and a metal conductor section is formed by either (i) laminating, on an insulating substrate, metal foil serving as wires, or (ii) applying metal foil over an insulator. Then, a part of the metal conductor section is chemically etched.

Further, there has been proposed such a method that wires are formed by simply printing a conductive paste with the use of an etched steel mask, a meshed screen mask, or the like.

Further, for example, Japanese Patent No. 2897409 (Tokkyo 2897409; registered on Mar. 12, 1999) (Patent Document 2) describes an IC package having bumps formed on edges thereof. The IC package is obtained in the following manner. First, a surface having no electrode formed thereon is covered with a resin. Next, a conductor pattern extending from an electrode of an IC chip is provided on the resin section substantially flush with a surface of the electrode of the IC chip. Then, sealing is carried out with the use of a covering resin such that a peripheral portion of the conductor pattern is exposed. Then, the bumps are formed on the peripheral portion.

In addition to the semiconductor chips, the sealing material, and the like, the conventional small package (CSP) requires a printed circuit board as its frame. The printed circuit board takes up a large part of the cost of material required for the manufacture of the CSP.

Meanwhile, the conventional wafer level CSP has an advantage in terms of the cost of manufacturing over the conventional CSP when a large number of small semiconductor ICs are mounted on a wafer and when the chip size is small. However, as long as the semiconductor ICs are processed in the form of a wafer, an outer side of one semiconductor IC belongs to another semiconductor IC. Therefore, each semiconductor IC inevitably has external connection pads or terminals formed on its surface. Accordingly, as the number of external connection pads increases, the center-to-center distance (pitch) between the external connection pads inevitably becomes shorter. When the distance between the external connection pads is small, the wires extending between the pads need to be narrowed or placed at shorter intervals. Moreover, the wires formed on the printed circuit board on which the wafer level CSP is mounted need to be narrowed or placed at shorter intervals. This requires an improvement in processing accuracy, which causes cost increase.

Further, the wafer level CSP has a size completely equal to that of the semiconductor ICs. However, various semiconductor ICs are normally different in size from one another. Therefore, as in the case of the conventional package, it is difficult to manufacture packages with predetermined outer dimensions. That is, in the process of manufacturing the wafer level CSP, it is basically necessary to dedicate different transportation trays, different test sockets, and different packing materials for semiconductor chips having different functions.

Further, the IC package described in Patent Document 2 is designed to accommodate a large number of pins, and has the bumps formed on the edges thereof. However, when the number of pins increases, the bumps inevitably make contact with one another.

### SUMMARY OF THE INVENTION

The present invention has as an object to provide: (i) a semiconductor device which makes it possible to place external connection pads at greater intervals, and which makes it possible to widen wires and to place the wires at greater intervals; and (ii) a method for manufacturing the semiconductor device.

In order to attain the foregoing object, a semiconductor device according to the present invention includes: a semiconductor chip having a plurality of electrode pads formed on a principal surface thereof; an insulating section having a surface flush with the principal surface; and external connection pads, which are provided on both (i) the principal surface and (ii) the surface of the insulating section flush with the principal surface, and which are electrically connected to the electrode pads.

According to the foregoing arrangement, each of the external connection pads connected to a substrate on which the semiconductor device is mounted can be provided in areas on both the insulating section and the semiconductor chip. That is, the external connection pad can be provided in a wider area.

The foregoing arrangement does not have the fan-in structure of the conventional wafer level CSP in which the external connection pads are formed solely on the semiconductor chip. Further, in the forgoing arrangement, the external connection pads are not formed solely on the insulating section. Therefore, it is possible to place the external connection pads at wider intervals. This makes it possible to widen the wires and place the wires at wider intervals. Thus, a high-quality semiconductor device can be provided which is capable accommodating a large number of pins, and which is free from shorting.

Thus, according to the foregoing arrangement, the external connection pads can be provided on both (i) the insulating section surrounding the semiconductor chip, (ii) and the principal surface of the semiconductor chip. This makes it possible to provide a package having a fan-out structure, which cannot be realized by the conventional wafer level CSP.

Further, since the insulating section is so formed as to be flush with the principal surface of the semiconductor chip, the wires, the external connection pads, and the like can be formed together. This makes it possible to reduce the cost of manufacturing.

Further, the foregoing arrangement does not employ a printed circuit board. Therefore, the forgoing arrangement can be manufactured at lower cost of material than the CSP, which employs a printed circuit board. This makes it possible to reduce the cost of manufacturing.

In order to attain the foregoing object, a method according to the present invention for manufacturing a semiconductor device includes: a mounting step of mounting, on a semiconductor chip mounting material, a plurality of semiconductor chips each having electrode pads formed on a principal surface thereof, so that the semiconductor chips are separated from one another, and that the principal surface of each of the semiconductor chips faces an adhesive surface of the semiconductor chip mounting material; a filling step of filling, with an insulating material, a space between the semiconductor chips mounted on the semiconductor chip mounting material, and covering, with the insulating material, a surface of each of the semiconductor chips opposite to the principal surface; a removing step of removing the semiconductor chip mounting material; and a wire-forming step of forming, on both (i) the principal surface of each of the semiconductor chips and (ii) a surface of the insulating material which surfaces are exposed by removing the semiconductor chip mounting material, wires including external connection pads which are electrically connected to the electrode pads.

The foregoing method makes it possible to manufacture a semiconductor device arranged such that each of the external connection pads connected to a substrate on which the semiconductor device is mounted is provided in areas on both the insulating section and the semiconductor chip. That is, the external connection pad can be provided in a wider area. Therefore, it is possible to place the external connection pads at wider intervals. This makes it possible to widen the wires and to place the wires at wider distances. Thus, a high-quality semiconductor device can be manufactured which is capable accommodating a large number of pins, and which is free from shorting. Thus, the external connection pads can be provided on both (i) the insulating section surrounding the semiconductor chip, and (ii) the principal surface of the semiconductor chip. This makes it possible to manufacture a package having a fan-out structure, which cannot be realized in the conventional wafer level CSP. Therefore, it is possible to manufacture, at a time, a large number of semiconductor devices which make it possible to place external connection pads at wider intervals, and which make it possible to widen wires and to place the wires at wider intervals.

Furthermore, in the manufacturing, only electrically good semiconductor chips are selected so as to be mounted on the semiconductor chip mounting material. Therefore, unlike the case of the conventional wafer level CSP, the cost of manufacturing is not affected by a change caused due to differences in defective rate among wafers. This makes it possible to always manufacture only good semiconductor devices at constant cost.

Further, because the insulating material and the principal surface of each of the semiconductor chips are so formed as to be flush with each other, a sealing resin, the wires, the external connection pads, and the like can be formed together. This makes it possible to reduce the cost of manufacturing.

Additional objects, features, and strengths of the present invention will be made clear by the description below. Further, the advantages of the present invention will be evident from the following explanation in reference to the drawings.

### BRIEF DESCRIPTION OF THE DRAWINGS

FIG. 1(a) is a cross-sectional view of a semiconductor device according to a first embodiment of the present invention.

FIG. 1(b) is a perspective view of the semiconductor device illustrated in FIG. 1(a).

FIG. 2 is a perspective view illustrating that, in a process of manufacturing the semiconductor device, semiconductor chips have been attached to a sheet material.

FIGS. 3(a), 3(b), and 3(c) are cross-sectional views illustrating the process of manufacturing the semiconductor device.

FIG. 4(a) is a plan view as viewed from a principal surface of the semiconductor chips from which the sheet material has been peeled in the process of manufacturing the semiconductor device.

FIG. 4(b) is a cross-sectional view taken along line A-A′ of FIG. 4(a).

FIG. 5(a) is a plan view as viewed from the principal surface of the semiconductor chip on which metal wires and external connection pads have been formed in the process of manufacturing the semiconductor device.

FIG. 5(b) is a cross-sectional view taken along line B-B′ of FIG. 5(a).

FIG. 6(a) is a plan view as viewed from the principal surface of the semiconductor chip on which a protective resin has been formed and an upper surface of the external connection pads has been exposed in the process of manufacturing the semiconductor device.

FIG. 6(b) is a cross-sectional view taken along line C-C′ of FIG. 6(a).

FIG. 7(a) is a cross-sectional view of a semiconductor device according to a second embodiment of the present invention.

FIG. 7(b) is a perspective view of the semiconductor device illustrated in FIG. 7(a).

FIG. 8 is a cross-sectional view of a semiconductor device according to a third embodiment of the present invention.

FIG. 9 is a cross-sectional view of a semiconductor device according to a fourth embodiment of the present invention.

FIG. 10(a) is a perspective view of a conventional semiconductor device.

FIG. 10(b) is a cross-sectional view of the conventional semiconductor device illustrated in FIG. 10(a).

### DESCRIPTION OF THE EMBODIMENTS

### First Embodiment

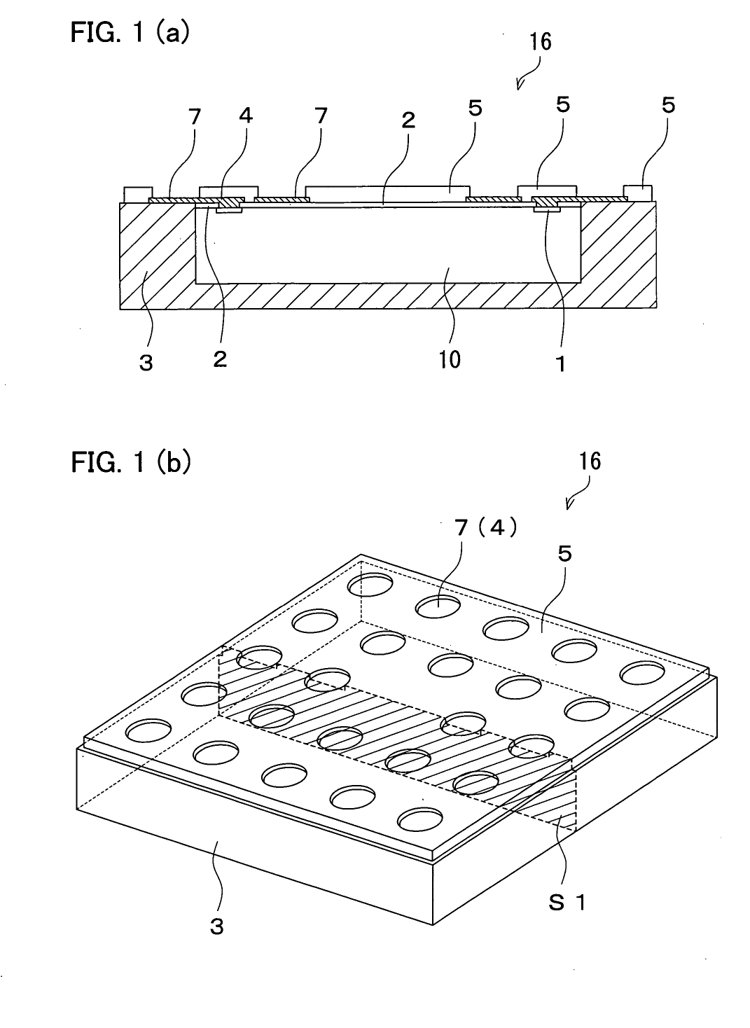

A first embodiment of the present invention will be described below with reference to FIGS. 1(a) to 6. Note that the present invention is not limited to this.

(An Arrangement of a Semiconductor Device)

First, an arrangement of a semiconductor device of the present embodiment will be described. FIG. 1(b) is a perspective view of a semiconductor device 16 of the present embodiment. FIG. 1(a) is a cross-sectional view taken along surface S1 of FIG. 1(b).

As illustrated in FIG. 1(a), the semiconductor device 16 of the present embodiment includes a semiconductor chip 10, a sealing resin (insulating section) 3, metal wires (wires) 4, external connection pads 7, and a protective resin 5.

The semiconductor chip 10 has electrode pads 1. The semiconductor chip 10 is covered with an insulating film 2 so that an upper surface of each of the electrode pads 1 is exposed. That is, the insulating film 2 is not applied over the upper surface of the electrode pad 1 so as to have an opening. Examples of the semiconductor chip 10 include an integrated circuit (LSI: large-scale integrated circuit) made up of a CPU (central processing unit), a memory, and the like.

The electrode pad 1 is incorporated into the semiconductor chip 10, and serves as an electric terminal including an input-output terminal of the semiconductor device 16. The material of the electrode pad 1 is not particularly limited as long as it is a conducting material, but the electrode pad 1 is preferably made of Al, Cu, or the like.

The insulating film 2 insulates the semiconductor chip 10 from an outside environment, and serves as a protective film for protecting the surface of the semiconductor chip 10 provided with the electrode pad 1. The insulating film 2 is formed of an inorganic film such as an oxide film or a nitride film. Furthermore, on the inorganic film, an organic film such as a polyimide film may be formed.

The sealing resin 3 is an insulating resin, and is formed on both (i) side surfaces of the semiconductor chip 10 and (ii) a rear surface of the semiconductor chip 10 opposite to the surface on which the electrode pad 1 is formed. The sealing resin 3 is made of an insulating resin such as an epoxy resin, a polyimide resin, or a silicone resin. That is, the sealing resin 3 is made of a resin that is hardened by heat, ultraviolet light, and the like.

The metal wires 4 are formed on a surface of the insulating film 2, on the electrode pad 1 not covered with the insulating film 2 (i.e., on the opening of the insulating film 2), and on the sealing resin 3. The metal wire 4 serves as a current film for flowing an electric current between the electrode pad 1 and the external connection pads 7. Note that the external connection pads 7 are part of the metal wire 4, and are formed through the same process as the metal wire 4 is formed.

The protective resin 5 protects the metal wire 4 formed on a principal surface of the semiconductor device 16, but does not protect the external connection pad 7. The protective resin 5 is preferably made of an insulating resin such as a polyimide resin, a polybenzooxazole (PBO) resin, or a benzocyclobutene (BCB) resin. The protective resin 5 covers both (i) the principal surface of the semiconductor chip 10 provided with the electrode pads 1 and (ii) a surface of the sealing resin 3 flush with the principal surface, in such a manner that the external connection pad 7 is at least exposed.

As described above, the semiconductor device 16 has, on both (i) the principal surface of the semiconductor chip 10 and (ii) the surface of the sealing resin 3 flush with the principal surface of the semiconductor chip 10, the external connection pad 7 which is electrically connected to the electrode pad 1.

According to the foregoing arrangement, the external connection pad 7 connected to a substrate on which the semiconductor device 16 is mounted can be provided in areas on both the sealing resin 3 and the semiconductor chip 10. That is, the external connection pad 7 can be provided in a wider area. The semiconductor device 16 does not have the fan-in structure of the conventional wafer level CSP in which the external connection pads are formed solely on the semiconductor chip. Neither is the semiconductor device 16 arranged such that the external connection pads (i.e., external connection terminals) are formed solely on the sealing resin 3. Therefore, it is possible to place the external connection pads at wider intervals. This makes it possible to widen the wires and to place the wires at wider intervals. Thus, a high-quality semiconductor device can be provided which is capable of accommodating a larger number of pins, and which is free from shorting.

As described above, the external connection pad 7 can be provided on both (i) the surface of the sealing resin 3 surrounding the semiconductor chip 10 and (ii) the principal surface of the semiconductor chip 10. Therefore, the semiconductor device 16 can be packaged so as to have a fan-out structure, which cannot be realized by the conventional wafer level CSP.

Further, since the sealing resin 3 is so formed as to be flush with the principal surface of the semiconductor chip 10, the metal wires 4 and the external connection pads 7 can be formed together. This makes it possible to reduce the cost of manufacturing.

The sealing resin 3 surrounding the side surfaces of the semiconductor chip 10 makes it possible to form packages with predetermined dimensions. That is, packages of a fixed size can be realized independently of the size of the semiconductor chip 10. This makes it possible to use (i) a common tray for transporting the packages, (ii) a common socket for testing the packages, and (iii) a common material for packing the packages. Accordingly, the cost can be reduced.

Further, the semiconductor device 16 does not employ a printed circuit board. Therefore, the semiconductor device 16 can be manufactured at lower cost of material than the CSP, which employs a printed circuit board. This makes it possible to reduce the cost of manufacturing.

(A Method for Manufacturing Semiconductor Devices)

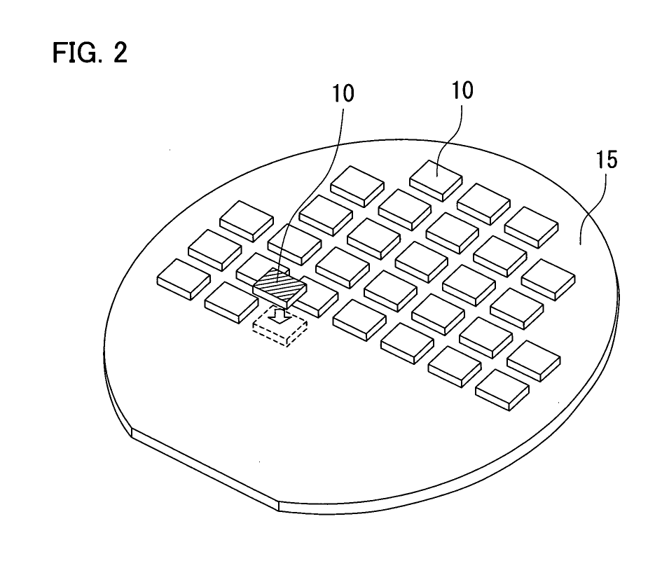

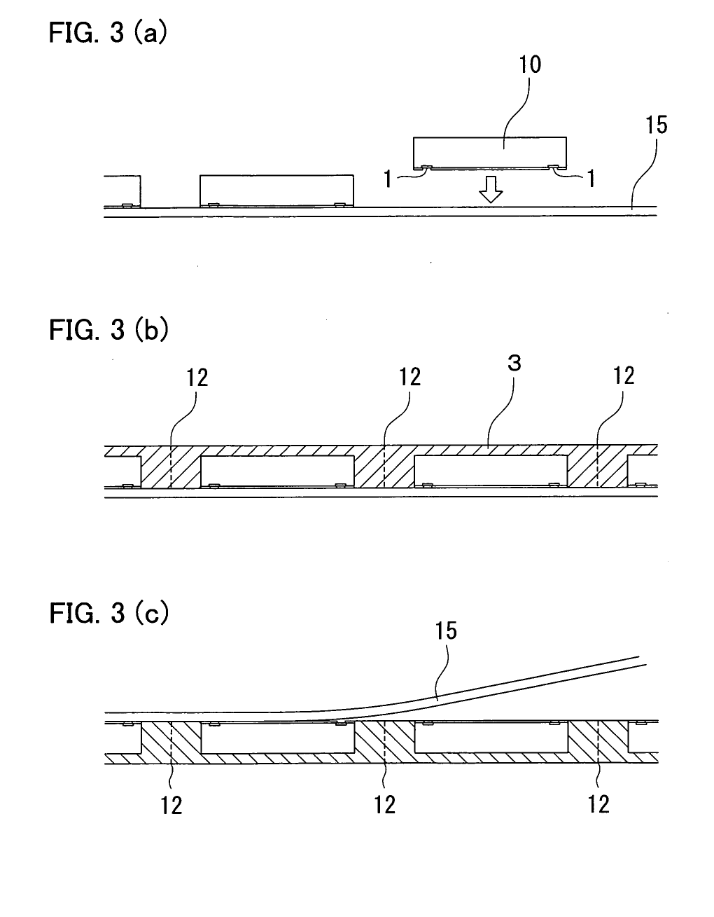

In the following, a method for manufacturing semiconductor devices 16 of the present embodiment will be described with reference to FIGS. 2 to 6. As illustrated in FIGS. 2 and 3(a), semiconductor chips 10 judged as good are taken out from a semiconductor wafer having semiconductor elements formed thereon. Each of the semiconductor chips 10 is mounted on an adhesive material (semiconductor chip mounting material) 15 so that an element surface of the semiconductor chip 10 on which the electrode pads 1 and the insulating film 2 are formed faces the adhesive material 15 (mounting step). FIG. 3(a) is a cross-sectional view of the semiconductor chips 10 and the like illustrated in FIG. 2. The adhesive material 15 needs to have adhesion at least on a surface on which the semiconductor chip 10 is mounted. The adhesive material 15 is preferably made of a material whose adhesion is reduced by heat treatment or ultraviolet irradiation. Examples of a material forming the adhesive material 15 include, but are not limited to, (i) a polyester-based heat peeling adhesive and (ii) an acrylic UV adhesive. The heat peeling adhesive is used where heat resistance is required. When the heat peeling adhesive is used, the adhesion can be reduced by heat treatment. When the acrylic UV adhesive is used, the adhesion can be reduced by ultraviolet irradiation. Further, as illustrated in FIG. 2, the adhesive material 15 is formed in advance so as to have a shape equivalent to that of the semiconductor wafer. With this, various apparatuses used for processing of a conventional wafer can be applied. When the adhesive material 15 is formed in advance so as to have the shape equivalent to that of the semiconductor wafer, the sealing resin 3 in which the semiconductor chips 10 (described later) are incorporated can be formed so as to have the shape equivalent to that of the semiconductor wafer. Accordingly, for example, the sealing resin 3 in which the semiconductor chips 10 are incorporated can be cut into individual semiconductor chips 10 with the use of a dicer, which is one example of the apparatuses used for processing of the conventional wafer. However, the shape of the adhesive material 15 is neither limited nor restricted to that described above.

In this case, the semiconductor chips 10 are mounted on the adhesive material 15 at regular intervals. For example, the semiconductor chips 10 each with the dimensions 3 mm×3 mm are mounted on the adhesive material 15 at 5 mm intervals, i.e., with a 2 mm space therebetween. Conventionally, when the external connection pads 7 are aligned in a 5×5 matrix (see FIG. 2), the external connection pads 7 are placed at a center-to-center distance (pitch) of 0.5 mm. According to the present invention, on the other hand, the external connection pads 7 can be placed at an increased pitch of 0.8 mm to 1.0 mm, since the side surfaces of each of the semiconductor chips are covered with the sealing resin 3.

Next, as illustrated in FIG. 3(b), the semiconductor chips 10 mounted on the adhesive material 15 are covered with the insulating sealing resin (insulating material) 3 so as to be embedded in the sealing resin 3 (filling step). The sealing resin 3 is made of a resin that is hardened by heat, ultraviolet light, and the like. Examples of the resin include an epoxy resin, a polyimide resin, and a silicone resin. Examples of the covering technique include transfer molding, printing, and dropping. Note that dotted lines 12 of FIG. 3(b) represents cutting lines at which the individual semiconductor chips are finally separated from one another.

Next, as illustrated in FIG. 3(c), the adhesive material 15 whose adhesion has been reduced by heat treatment or ultraviolet irradiation is removed from the sealing resin 3 in which the semiconductor chips 10 are incorporated (removing step). Then, the element surface of each of the semiconductor chips 10 on which the electrode pads 1 are formed is exposed. When the adhesive material 15 is a sheet-like material, the adhesive material 15 can be removed by way of peeling. Therefore, the adhesive material 15 can be easily removed from the sealing resin 3 in which the semiconductor chips 10 are incorporated.

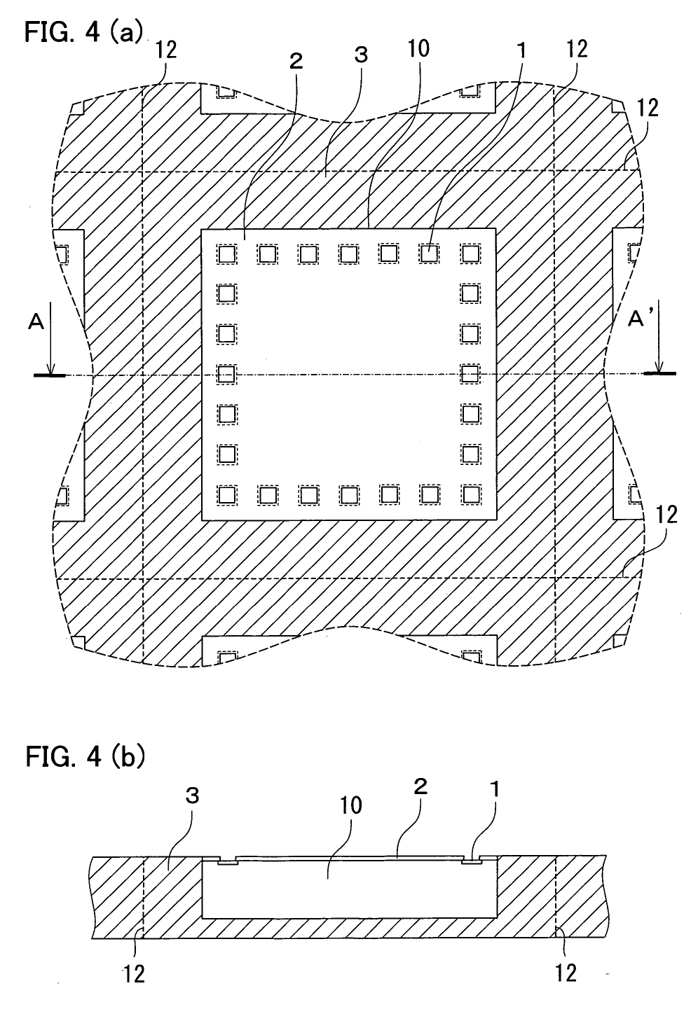

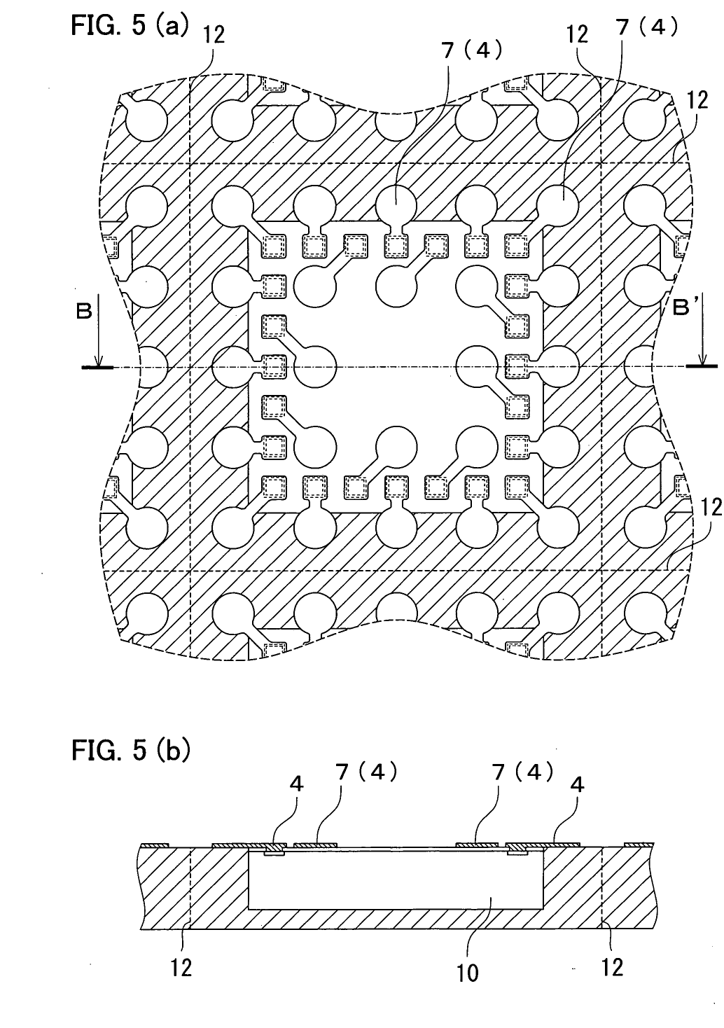

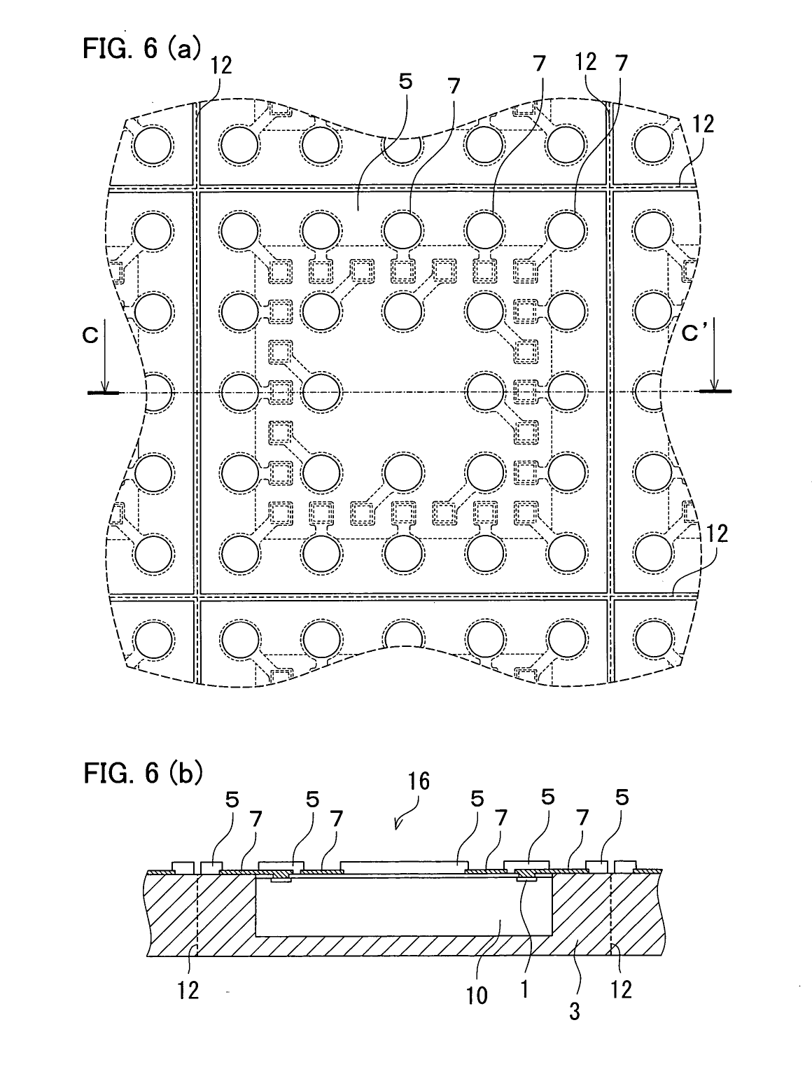

Here, the semiconductor chips 10 are incorporated in the sealing resin 3 at regular intervals, and the sealing resin 3 has the shape equivalent to that of the semiconductor wafer. The semiconductor chips 10 are placed one after another in the sealing resin 3. FIG. 4(a) is a plan view of the sealing resin 3 in which the semiconductor chips 10 are incorporated. Specifically, FIG. 4(a) is a plan view of the surface of the sealing resin 3 from which the adhesive material 15 has been removed, i.e., the surface of the sealing resin 3 on which the semiconductor chips 10 are formed. More specifically, FIG. 4(a) illustrates one of the semiconductor chips 10 and an area surrounding the semiconductor chip 10. FIG. 4(b) is a cross-sectional view taken along line A-A′ of FIG. 4(a). The dotted lines 12 of FIGS. 4(a) and 4(b) represents the cutting lines at which the individual semiconductor chips are finally separated from one another. The same applies to FIGS. 5(a) and 5(b) and FIGS. 6(a) and 6(b).

Next, a metal thin film (not shown) is formed on the entire surface of the sealing resin 3 on which the element surface of the semiconductor chips 10 formed at regular intervals is exposed. The metal thin film is made, for example, of Au/Ti, Au/TiW, or Au/Cu/Cr. The metal thin film is formed, for example, by sputtering. Note that Au/Ti means an alloy of titanium and gold. Similarly, Au/TiW and Au/Cu/Cr are alloys. The metal thin film preferably has a thickness of 0.1 μm to 0.3 μm, for example.

Then, a photosensitive resist is applied over the metal thin film. Exposure and development are carried out such that the photosensitive resist has an opening (not shown) which corresponds to portion that requires metal plating (i.e., rewired portion). That is, the opening is formed that corresponds to a portion extending from the upper surface of the electrode pads 1 of the semiconductor chip 10 to a portion on which the external connection pads 7 are formed.

In the opening of the photosensitive resist, wiring plated metal (not shown) such as Cu is formed by electrolytic plating. Thereafter, the photosensitive resist is removed, and the metal thin film which is not covered with the wiring plated metal and which has been formed by sputtering is removed by etching (wire-forming step). In this manner, the metal wires 4 and the external connection pads 7 can be formed simultaneously. FIG. 5(a) is a plan view of the sealing resin 3 in which the semiconductor chips 10 are incorporated. Specifically, FIG. 5(a) is a plan view of the surface of the sealing resin 3 on which the wires have been formed, i.e., the surface of the sealing resin 3 on which the semiconductor chip 10 are formed. FIG. 5(b) is a cross-sectional view taken along line B-B′ of FIG. 5(a)

See FIG. 6(a) and FIG. 6(b), which is a cross-sectional view taken along line C-C′ of FIG. 6(a). The protective resin 5 having an insulating property is formed on the surface of the sealing resin 3 on which the metal wires 4 are formed, with the semiconductor chips 10 being disposed in the sealing resin 3 at regular intervals. The protective resin 5 is formed so that at least the external connection pads 7 are exposed. The protective resin 5 is formed, for example, by screen printing, spin coating, or dripping, in accordance with liquid properties of a liquid resin. The following explains a specific example in which the formation is carried out by way of screen printing. Polyimide ink such as block copolymer polyimide is printed on the surface on which the metal wires 4 are formed. The printing is carried out by screen printing using a screen mask. The polyimide ink is hardened by heat treatment so that the protective resin 5 is formed. The protective resin 5 preferably has a thickness of 10 μm to 50 μm, for example. The protective resin 5 is formed so as to have openings (e.g., circular openings), which correspond to portions on which the external connection pads 7 are formed. Preferably, the protective resin 5 is not formed on the dotted lines 12 at which the semiconductor devices 16 are finally separated from one another by dicing. This makes it easy to carry out the dicing. Further, for example, the protective resin 5 may be made of a solid resin and formed by transfer molding. Further, the protective resin 5 may be made of a photosensitive polymer and formed by photolithography.

Furthermore, the sealing resin 3 which has the shape equivalent to that of the semiconductor wafer and in which the semiconductor chips 10 are formed at regular intervals is cut into the individual semiconductor chips with the use of a dicing wheel or a laser (cutting step). With this, the semiconductor device 16 illustrated in FIG. 1(a) can be formed. In this cutting step, the sealing resin 3 is cut so that the semiconductor device 16 has a predetermined size. This makes it possible to form packages with predetermined dimensions. That is, packages of a fixed size can be realized independently of the size of the semiconductor chips 10. This makes it possible to use (i) a common tray for transporting the packages, (ii) a common socket for testing the packages, and (iii) a common material for packing the packages. Accordingly, the cost can be reduced.

According to the foregoing manufacturing method, the semiconductor device 16 can be manufactured such that the external connection pad 7 connected to a substrate on which the semiconductor device 16 is mounted is provided in areas on both the sealing resin 3 and the semiconductor chip 10. That is, the external connection pad 7 can be provided in a wider area. Therefore, it is possible to place the external connection pads 7 at larger distances from one another. This makes it possible to widen the metal wires 4 and to place the metal wires 4 at wider intervals. Thus, a high-quality semiconductor device 16 can be manufactured which is capable accommodating a large number of pins, and which is free from shorting. As described above, the external connection pads 7 can be provided on both (i) the sealing resin 3 surrounding the semiconductor chip 10, and (ii) the principal surface of the semiconductor chip 10. This makes it possible to manufacture, at a time, a large number of packages each having a fan-out structure, which cannot be realized in the conventional wafer level CSP.

Furthermore, in the manufacturing, only electrically good semiconductor chips 10 are selected so as to be mounted on the adhesive material 15. Therefore, unlike the case of the conventional wafer level CSP, the cost of manufacturing is not affected by a change caused due to differences in defective rate among wafers. This makes it possible to always manufacture only good semiconductor devices 16 at constant cost.

Further, because the sealing resin 3 and the principal surface of each of the semiconductor chips 10 are so formed as to be flush with each other, the metal wires 4, the external connection pads 7, the protective resin 5, and the like can be formed together. This makes it possible to reduce the cost of manufacturing.

### Second Embodiment

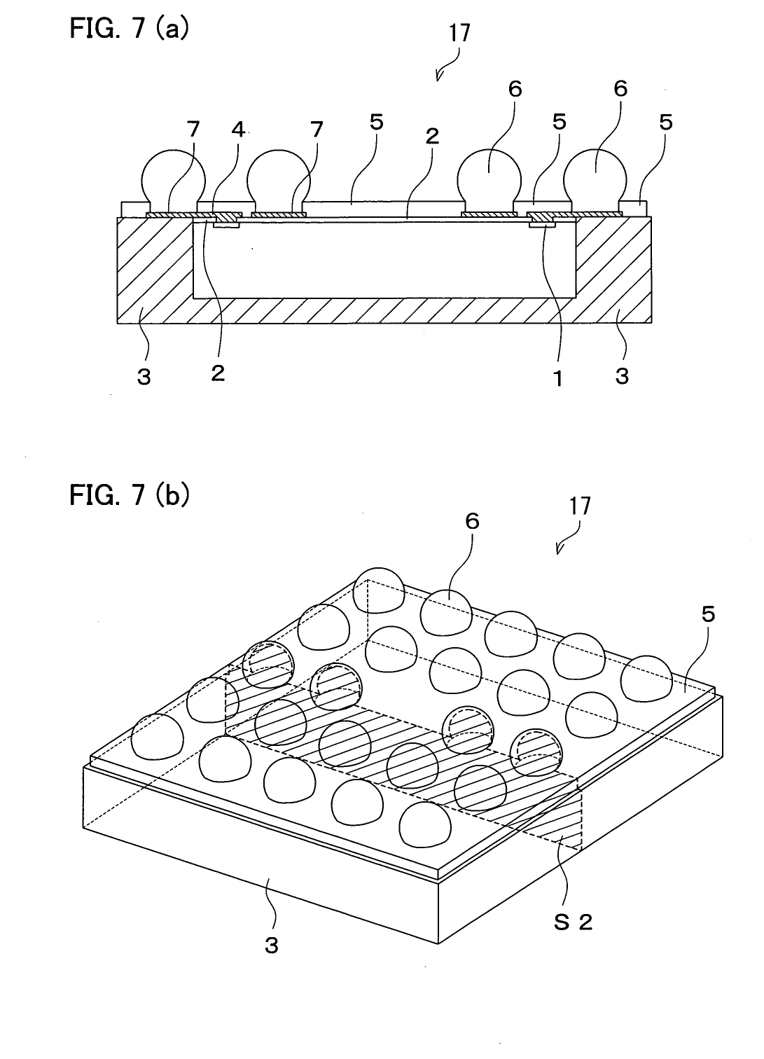

A second embodiment of the present invention will be described below with reference to FIGS. 7(a) and 7(b). For convenience of explanation, components having the same functions as those described in the first embodiment are given the same reference numerals, and no explanation will be given to the components. FIG. 7(b) is a perspective view of a semiconductor device 17 of the present embodiment. FIG. 7(a) is a cross-sectional view taken along surface S2 of FIG. 7(b).

As illustrated in FIG. 7(a), the semiconductor device 17 includes external connection terminals 6, respectively connected to the external connection pads 7, in addition to the arrangement of the semiconductor device 16 described in the first embodiment with reference to FIGS. 1(a) and 1(b). As the external connection terminals 6, spherical solder balls are used, for example. For example, the external connection terminals 6 are formed in the following manner. That is, the spherical solder balls are put on a flux attached to the external connection pads 7. Then, the spherical solder balls are subjected to reflowing.

The external connection terminals 6 may be formed under such conditions that the semiconductor chips 10 are placed one after another in the sealing resin 3 (i.e., under such conditions that the semiconductor chips 10 are formed at regular intervals in the sealing resin 3). Alternatively, the external connection terminals 6 may be formed under such conditions that the semiconductor chips 10 have been separated from one another. Further, the external connection terminals 6 can also be formed in the following manner. That is, a soldering paste is screen-printed, and then is subjected to reflowing. In this case, the external connection terminals 6 can be more effectively formed under such conditions that the semiconductor chips 10 are placed one after another in the sealing resin 3.

Like the semiconductor device 16 of the first embodiment, the semiconductor device 17 of the present embodiment makes it possible to place the external connection pads 7 at greater intervals. Accordingly, it is possible to widen the wires and to place the wires at wider intervals. Further, the external connection terminals 6 can also be placed at greater intervals.

### Third Embodiment

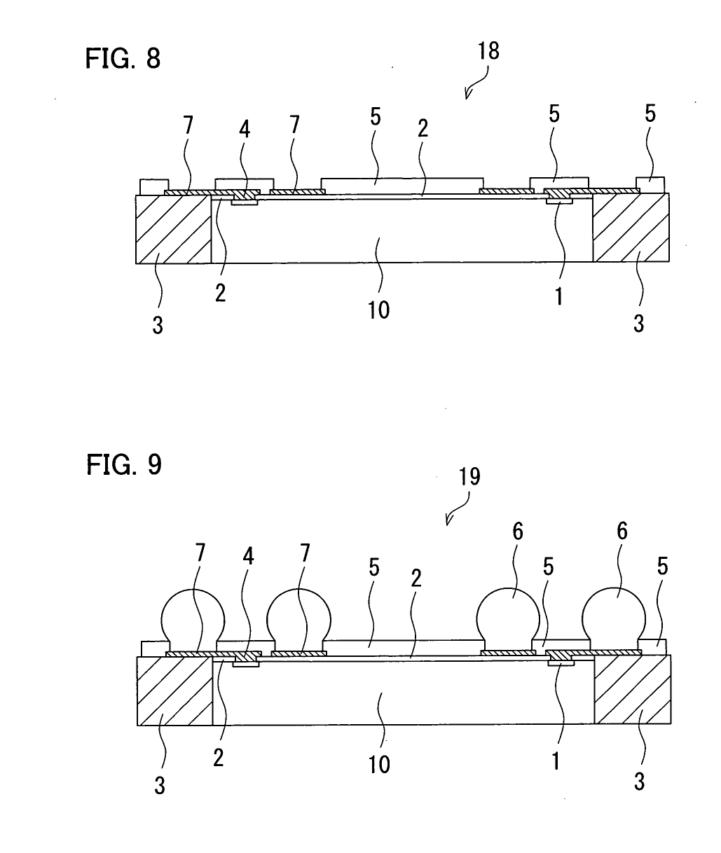

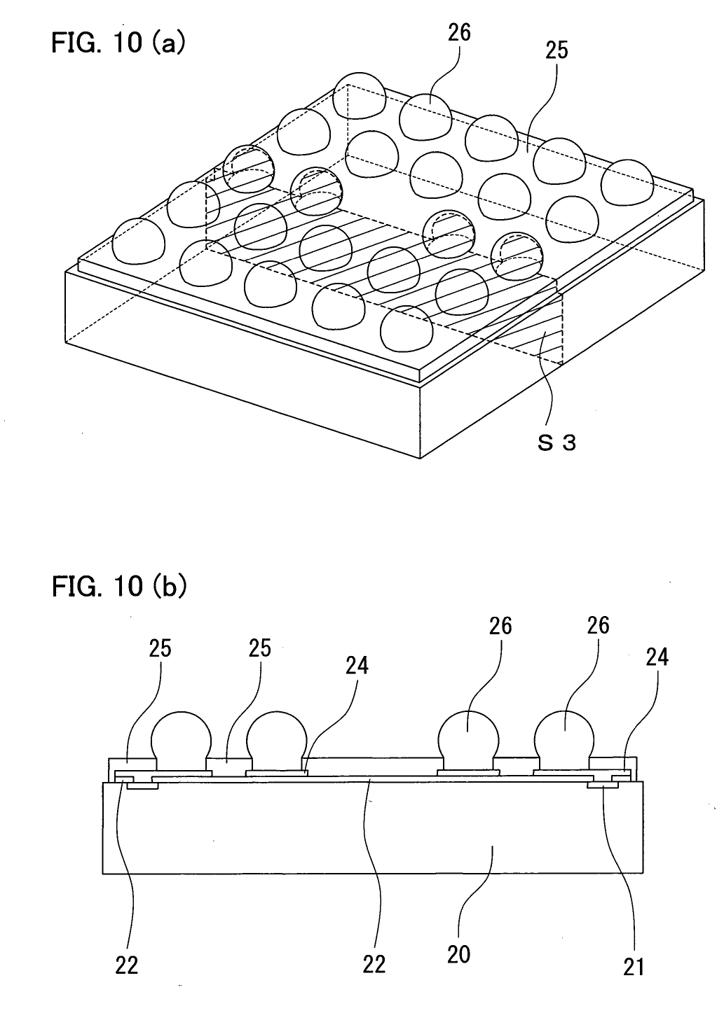

A third embodiment of the present invention will be described below with reference to FIG. 8. For convenience of explanation, components having the same functions as those described in the first embodiment are given the same reference numerals, and no explanation will be given to the components.

FIG. 8 is a cross-sectional view of a semiconductor device 18 of the present embodiment. As illustrated in FIG. 8, the semiconductor device 18 is different from the semiconductor device 16 illustrated in FIG. 1(a) in that the surface of the semiconductor chip 10 opposite to the principal surface is exposed. The semiconductor device 18 is manufactured in the following manner. That is, after the protective resin 5 has been formed as described with reference to FIGS. 6(a) and 6(b), the sealing resin 3 covering the surface of the semiconductor chip 10 opposite to the principal surface is grinded with the use of a backgrinding machine (grinding step). The grinding may be carried out after the external connection terminals 6 have been formed. The grinding step causes the semiconductor device 18 to become thinner. Thus, when the semiconductor device 18 is mounted on a substrate installed in an apparatus, the semiconductor device 18 occupies a smaller space in the apparatus. Further, since the semiconductor device 18 is arranged such that the surface of the semiconductor chip 10 opposite to the principal surface is exposed, a heat dissipating material such as a heat spreader or a heat sink can be put on or bonded to the exposed surface. With this, a semiconductor chip requiring a large amount of power can be applied to the semiconductor device 18.

### Fourth Embodiment

A fourth embodiment of the present invention will be described below with reference to FIG. 9. For convenience of explanation, components having the same functions as those described in the first embodiment are given the same reference numerals, and no explanation will be given to the components.

FIG. 9 is a cross-sectional view of a semiconductor device 19 of the present embodiment. As illustrated in FIG. 9, the semiconductor device 19 is different from the semiconductor device 16 illustrated in FIG. 7(a) in that the surface of the semiconductor chip opposite to the principal surface is exposed. As in the case of the third embodiment, the semiconductor device 19 is manufactured in the following manner. That is, the sealing resin 3 covering the surface of the semiconductor chip 10 opposite to the principal surface is grinded with the use of a backgrinding machine (grinding step). The grinding may be carried out after the external connection terminals 6 have been formed. Alternatively, the grinding may be carried out before the external connection terminals 6 are formed. This grinding step causes the semiconductor device 19 to become thinner. Thus, when the semiconductor device 19 is mounted on a substrate installed in an apparatus, the semiconductor device 19 occupies a smaller space in the apparatus. Further, since the semiconductor device 19 is arranged such that the surface of the semiconductor chip 10 opposite to the principal surface is exposed, a heat dissipating material such as a heat spreader or a heat sink can be put on or bonded to the exposed surface. With this, a semiconductor chip requiring a large amount of power can be applied to the semiconductor device 19.

As described above, in addition to the foregoing arrangement, the semiconductor device according to the present invention may be arranged such that, when the principal surface of the semiconductor chip serves as an upper surface of the semiconductor chip, the insulating section covers both (i) side surfaces of the semiconductor chip and (ii) a surface of the semiconductor chip opposite to the principal surface.

According to the foregoing arrangement, the insulating section surrounding the side surfaces of the semiconductor chip makes it possible to form packages with predetermined dimensions. That is, packages of a fixed size can be realized independently of the size of the semiconductor chip. This makes it possible to use (i) a common tray for transporting the packages, (ii) a common socket for testing the packages, and (iii) a common material for packing the packages. Accordingly, the cost can be reduced.

In addition to the foregoing arrangement, the semiconductor device according to the present invention may be arranged such that: when the principal surface of the semiconductor chip serves as an upper surface of the semiconductor chip, the insulating section covers side surfaces of the semiconductor chip; and a surface of the semiconductor chip opposite to the principal surface is exposed.

According to the foregoing arrangement, as in the case of the semiconductor device arranged such that the surface of the semiconductor chip opposite to the principal surface is covered with the insulating section, each of the external connection pads connected to a substrate on which the semiconductor device is mounted can be provided in areas on both the insulating section and the semiconductor chip. Since the external connection pad can be provided in a wider area, it is possible to place the external connection pads at wider intervals. This makes it possible to widen wires and to place the wires at wider intervals. Thus, a high-quality semiconductor device can be provided which is capable of accommodating a large number of pins, and which is free from shorting. Thus, the external connection pad can be provided on both (i) the insulating section surrounding the semiconductor chip, (ii) and the principal surface of the semiconductor chip. This makes it possible to provide a package having a fan-out structure, which cannot be realized by the conventional wafer level CSP.

Furthermore, since the semiconductor device according to the present invention is arranged such that the surface of the semiconductor chip opposite to the principal surface is exposed, the semiconductor device does not become thick in a direction perpendicular to the principal surface. Therefore, the semiconductor device does not occupy a larger space in a thickness direction even when mounted on a substrate installed in an apparatus. Further, since the surface of the semiconductor chip opposite to the principal surface is exposed, a heat dissipating material such as a heat spreader or a heat sink can be put on or bonded to the exposed surface. With this, a semiconductor chip requiring a larger amount of power can be applied to the semiconductor device.

In addition to the foregoing arrangement, the semiconductor device according to the present invention may further include a protective resin for covering the principal surface of the semiconductor chip so that the external connection pads are exposed.

The foregoing arrangement makes it possible to protect the wires other than the external connection pads on the principal surface of the semiconductor device.

In addition to the foregoing arrangement, the semiconductor device according to the present invention may be arranged such that the external connection pads are provided with external connection terminals, respectively.

According to the foregoing arrangement, since the external connection pads are so formed as to be placed at wider intervals, the external connection terminals can also be mounted at wider intervals. This makes it possible to provide a semiconductor device capable of accommodating a large number of pins.

In addition to the foregoing method, the method of the present invention may further include a mounting step of mounting external connection terminals on the external connection pads, respectively.

According to the foregoing method, since the external connection pads are so formed as to be placed at wider intervals, the external connection terminals can also be mounted at wider intervals. This makes it possible to provide a semiconductor device capable of accommodating a large number of pins.

In addition to the foregoing method, the method of the present invention may further include a cutting step of cutting the insulating material between the semiconductor chips, so as to separate the semiconductor chips from one another.

According to the foregoing method, the insulating material is cut in the cutting step such that each of the semiconductor devices has a predetermined size. This makes it possible to form packages with predetermined dimensions. That is, packages of a fixed size can be realized independently of the size of each of the semiconductor chips. This makes it possible to use (i) a common tray for transporting the packages, (ii) a common socket for testing the packages, and (iii) a common material for packing the packages. Accordingly, the cost can be reduced.

In addition to the foregoing method, the method of the present invention may further include a grinding step of grinding the insulating material covering the surface of each of the semiconductor chips opposite to the principal surface, so as to expose the surface of the semiconductor chip opposite to the principal surface.

According to the foregoing method, the grinding causes the semiconductor device to become thinner. Therefore, the semiconductor device does not occupy a larger space in a thickness direction even when mounted on a substrate installed in an apparatus. Further, since the surface of the semiconductor chip opposite to the principal surface is exposed, a heat dissipating material such as a heat spreader or a heat sink can be put on or bonded to the exposed surface. With this, a semiconductor chip requiring a larger amount of power can be applied to the semiconductor device.

In addition to the foregoing method, the method of the present invention may be arranged such that: the semiconductor chip mounting material is a sheet-like material; and the sheet-like material is removed in the removing step.

According to the foregoing arrangement, the semiconductor chip mounting material is removed by way of peeling. Therefore, the semiconductor chip mounting material can be easily removed.

In addition to the foregoing method, the method of the present invention may be arranged such that the semiconductor chip mounting material has a size substantially equal to the size of a semiconductor wafer.

According to the foregoing method, since the semiconductor chip mounting material has the size substantially equal to the size of the semiconductor wafer, various apparatuses for manufacturing the conventional wafer level CSP can be applied. This makes it unnecessary to spend an excessive amount of money on various apparatuses for manufacturing the semiconductor chip.

A semiconductor device according to the present invention may include: a semiconductor chip having a plurality of electrode pads formed on a principal surface thereof; an insulating section, which covers both (i) side surfaces of the semiconductor chip and (ii) a surface of the semiconductor chip opposite to the principal surface, and which is so formed as to be flush with the principal surface of the semiconductor chip; conductor sections, which are formed on both the principal surface and the insulating section flush with each other, and which make electrical connection between (I) the electrode pads of the semiconductor chip and (II) external connection pads formed on the insulating section; and an insulating layer for carrying out covering such that the external connection pads formed on the insulating section are finally exposed, the external connection pads being formed directly on both the principal surface and the insulating section flush with each other.

Further, a semiconductor device according to the present invention may include: a semiconductor chip having a plurality of electrode pads formed on a principal surface thereof; an insulating section, which covers only side surfaces of the semiconductor chip, and which is so formed as to be flush with the principal surface of the semiconductor chip; conductor sections, which are formed on both the principal surface and the insulating section flush with each other, and which make electrical connection between (I) the electrode pads of the semiconductor chip and (II) external connection pads formed on the insulating section; and an insulating layer for carrying out covering such that the external connection pads formed on the insulating section finally are exposed, the external connection pads being formed on both the principal surface and the insulating section flush with each other, a surface of the semiconductor chip opposite to the principal surface being exposed.

Further, in addition to the foregoing arrangement, the semiconductor device according to the present invention may be arranged such that each of the external connection pads formed on the insulating section and each of the conductor sections making the electrical connection may be simultaneously formed in one piece through a single process.

Further, in addition to the foregoing arrangement, the semiconductor device according to the present invention may be arranged such that the external connection pads formed on the insulating section are provided with protruding terminals for use in external connection.

Further, in addition to the foregoing arrangement, the semiconductor device according to the present invention may be arranged such that the protruding terminals are formed by way of reflowing carried out after either (i) mounting of a ball containing solder, or (ii) printing of paste solder.

Further, in addition to the foregoing arrangement, the semiconductor device according to the present invention may be arranged such that the insulating section covering both (i) the side surfaces of the semiconductor chip and (ii) the surface of the semiconductor chip opposite to the principal surface is made by way of printing, transfer molding, dispensing, or spin coating of an insulating sealing material.

Further, in addition to the foregoing arrangement, the semiconductor device according to the present invention may be arranged such that the conductor sections are formed by way of deposition, plating, photolithography, or etching.

Further, in addition to the foregoing arrangement, the semiconductor device according to the present invention may be arranged such that: the insulating layer for carrying out the covering such that the external connection pads formed on the insulating section are finally exposed is formed by way of printing or spin coating; and the external connection pads formed on the insulating section are exposed by way of photolithography or etching.

Further, a method according to the present invention for manufacturing a semiconductor device may include the steps of: separating, into individual semiconductor chips, a semiconductor wafer having elements formed on a principal surface thereof; mounting, on a sheet material having an adhesive formed on a surface thereof, the semiconductor chips so that the semiconductor chips are placed at distances from one another, and that a principal surface of each of the semiconductor chips makes contact with the surface of the sheet material; filling, with an insulating sealing material, a space between the semiconductor chips mounted on the sheet material, and covering, with the insulating sealing material, a surface of each the semiconductor chips opposite to the principal surface; peeling and removing the sheet material; depositing a metal thin film entirely on a surface from which the sheet material has been peeled and removed; patterning, on the metal thin film, metal wires by way of photolithography and plating; chemically etching the metal thin film between the metal wires; and patterning an insulating material by way of printing or photolithography so that a portion of each of the wires is exposed, the steps being carried out in this order.

Further, in addition to the foregoing method, the method may be arranged such that: the insulating material covering the surface of each of the semiconductor chips opposite to the principal surface is grinded so that the surface of the semiconductor chip opposite to the principal surface is exposed.

Further, in addition to the foregoing method, the method may include the steps of: mounting, on the exposed portion of the wire, a terminal containing solder; and separating the semiconductor chips from one another, the steps being carried out in random order.

The embodiments and concrete examples of implementation discussed in the foregoing detailed explanation serve solely to illustrate the technical details of the present invention, which should not be narrowly interpreted within the limits of such embodiments and concrete examples, but rather may be applied in many variations within the spirit of the present invention, provided such variations do not exceed the scope of the patent claims set forth below.

What is claimed is:

1. A semiconductor device, comprising:
a semiconductor chip having a plurality of electrode pads formed on a principal surface thereof;
an insulating section having a surface flush with the principal surface; and
external connection pads, which are provided on both (i) the principal surface and (ii) the surface of the insulating section flush with the principal surface, and which are electrically connected to the electrode pads.

2. The semiconductor device as set forth in claim 1, wherein, when the principal surface of the semiconductor chip serves as an upper surface of the semiconductor chip, the insulating section covers both (i) side surfaces of the semiconductor chip and (ii) a surface of the semiconductor chip opposite to the principal surface.

3. The semiconductor device as set forth in claim 1, wherein:
when the principal surface of the semiconductor chip serves as an upper surface of the semiconductor chip, the insulating section covers side surfaces of the semiconductor chip; and
a surface of the semiconductor chip opposite to the principal surface is exposed.

4. The semiconductor device as set forth in claim 1, further comprising a protective resin for covering the principal surface of the semiconductor chip so that the external connection pads are exposed.

5. The semiconductor device as set forth in claim 1, wherein the external connection pads are provided with external connection terminals.

6. A method for manufacturing a semiconductor device, the method comprising:
a mounting step of mounting, on a semiconductor chip mounting material, a plurality of semiconductor chips each having electrode pads formed on a principal surface thereof, so that the semiconductor chips are separated from one another, and that the principal surface of each of the semiconductor chips faces an adhesive surface of the semiconductor chip mounting material;
a filling step of filling, with an insulating material, a space between the semiconductor chips mounted on the semiconductor chip mounting material, and covering, with the insulating material, a surface of each of the semiconductor chips opposite to the principal surface;
a removing step of removing the semiconductor chip mounting material; and
a wire-forming step of forming, on both (i) the principal surface of each of the semiconductor chips and (ii) a surface of the insulating material which surfaces have been exposed by removing the semiconductor chip mounting material, wires including external connection pads which are electrically connected to the electrode pads.

7. The method as set forth in claim 6, further comprising a mounting step of mounting external connection terminals on the external connection pads.

8. The method as set forth in claim 6, further comprising a cutting step of cutting the insulating material between the semiconductor chips, so as to separate the semiconductor chips.

9. The method as set forth in claim 6, further comprising a grinding step of grinding the insulating material covering the surface of each of the semiconductor chips opposite to the principal surface, so as to expose the surface of the semiconductor chip opposite to the principal surface.
